(19) United States
(12) Patent Application Publication
(10) Pub. No.: US 2010/0006420 A1
(43) Pub. Date: Jan. 14, 2010

(54) INLINE INTERLAYER HEATER APPARATUS

(75) Inventors: Thomas Larson Greenberg, Berkeley, CA (US); Thanh Thien Ha, San Jose, CA (US); Larry Douglas Monroe, Hollister, CA (US); Sam Vi Luong, San Jose, CA (US); Chinh Thien Dao, San Jose, CA (US); Hung Tuan Nguyen, San Jose, CA (US)

Correspondence Address: Shumaker & Sieffert, P.A., 1625 Radio Drive, Suite 300, Woodbury, MN, 55125, US

(73) Assignee: Seagate Technology LLC, Scotts Valley, CA (US)

(21) Appl. No.: 12/169,154

(22) Filed: Jul. 8, 2008

(51) Int. Cl. C23C 14/00

(52) U.S. Cl. 204/192.12; 204/298.09

(57) ABSTRACT

An apparatus for making a magnetic recording medium, including a quartz lamp within a sputtering chamber to heat the medium between the application of layers and without disruption to the vacuum integrity of the sputtering system. A process using the apparatus for manufacturing the magnetic recording medium is also claimed.

### BACKGROUND

The increasing demands for higher areal recording density impose increasingly greater demands on thin film magnetic recording media in terms of coercivity (Hc); magnetic remanance (Mr); coercivity squareness (S*); medium noise, eg., signal-to-medium noise ratio (SMNR); and narrow track recording performance. It is extremely difficult to produce a magnetic recording medium satisfying such demanding requirements.

The linear recording density can be increased by decreasing the medium noise, as by maintaining very fine magnetically decoupled grains in the magnetic layer of the magnetic medium. Medium noise is a dominant factor restricting increased recording density of high-density magnetic hard disk drives, and is attributed primarily to inhomogeneous grain size and intergranular exchange coupling in the magnetic layer. Accordingly, in order to increase linear density, medium noise must be minimized by suitable microstructure control of the magnetic layer and other layers of the magnetic medium.

The microstructure and uniaxial anisotropy of the magnetic layer and others layers of the magnetic medium is determined by both the composition of the layers as well as the conditions for reactive sputtering for depositing the layers on the medium. The microstructure and uniaxial anisotropy could be controlled in several ways in the soft magnetic thin film materials. One method is post-deposition annealing while applying a magnetic field. However, this method causes complications in the disk manufacturing process, because the application of heat during the manufacturing process is difficult. Due to the environment within the sputtering chamber, typical heating devices cannot be used. Standard heaters will be destroyed by the harsh conditions. Removing the substrates from the vacuum sputtering chamber and inserting them into a new vacuum sputtering chamber increases costs to undesirable levels. This is especially true in most modern sputtering chamber designs used for the manufacture of magnetic recording media, which are inline pass-by sputtering chambers. In these chamber designs, the substrate material travels through the chamber along a path, passing a number of sputtering cathodes. As the substrate passes the sputtering cathodes a series of layers of material are deposited on the substrate. Thus, in order to heat the substrate immediately after the deposition of a layer, it is necessary that the heater be within the sputtering chamber, or that the substrates be removed from the vacuum chamber and then reinserted for further deposition.

Due to the foregoing challenges, heating of the substrates between layers may be considered uneconomical. However, heating the substrates is also desirable prior to the application of a layer for improving the mobility of the sputtered material. Thus, the sputtered atoms are more capable of moving on the substrate surface until they reach a stable location. Again, in order to retain a high temperature, it is desirable to heat the substrate during the process of applying layers of material. However, as stated above, conventional heaters cannot withstand the harsh conditions of the sputtering chamber, and it is undesirable to remove the substrates from vacuum and reinsert them.

Although most heaters are incapable of operating within the sputtering chamber, some heaters have been used. For example, metal heater rods with internal resistive heater elements therein, e.g. cal rod heaters, have been used within sputtering chambers. Although they are capable of operating in a sputtering chamber, cal rod heaters have a very slow response time. Normally, these heaters are very slow to both reach a desirable temperature, and to cool down. This has two negative impacts. The first, is that their inability to heat quickly slows production time, thereby increasing costs. Second, the desired temperatures are usually extraordinarily high, and if the heaters retain this temperature for an extended period it can destroy elements within the sputtering chamber. Thus, there is a need for a heater that can operate within a sputtering chamber, between the application of layers of material that has a quick response time.

Another challenge related to the use of heaters inline in a sputtering chamber is that heating may only be required at certain locations for certain processes. However, the manufacturing apparatuses used for sputtering layers on the substrates are very long and expensive including a large number of locations where sputtering cathodes may be placed. It would be uneconomical to create an entire manufacturing apparatus for each possible configuration that includes a heater. Thus, there is a desire for an inline heater that may be used in combination with pre-existing sputtering apparatuses.

### SUMMARY OF THE INVENTION

The embodiments of the invention relate to a pass-by sputtering chamber, comprising a path along which substrates progress as layers are sputtered thereon; a sputtering cathode disposed at a first location along the path; and an inline heater disposed at a second location along the path, wherein the inline heater comprises at least one quartz lamp.

As will be realized, this invention is capable of other and different embodiments, and its details are capable of modifications in various obvious respects, all without departing from this invention. Accordingly, the drawings and description are to be regarded as illustrative in nature and not as restrictive. These and various other features and advantages will be apparent from a reading of the following detailed description.

### BRIEF DESCRIPTION OF THE DRAWINGS

FIG. 1 is a view of a magnetic disk drive.

FIG. 2 is a schematic representation of the film structure in accordance with a magnetic recording medium.

FIG. 3 is perspective view of a magnetic head and a magnetic disk.

FIG. 4 is a schematic view of an inline sputtering apparatus and quartz heating lamps of the present invention.

### DETAILED DESCRIPTION

This invention relates to an apparatus for making a recording media, such as thin film magnetic recording disks, and to a method of manufacturing the media. The invention has particular applicability to a highly flexible apparatus and method for manufacturing magnetic recording media having a two or more magnetic layers.

In one embodiment, the invention provides a pass-by sputtering chamber that includes a sputtering cathode and an inline heater. Substrates pass through the sputtering chamber along a manufacturing path. Each of the sputtering cathode and the inline heater are provided at different locations along the path in the sputtering chamber. The inline heater includes at least one quartz lamp so that it can operate within the sputtering chamber and have fast response time.

In another embodiment, the invention provides a method of forming layers on a substrate. The method includes providing a manufacturing path within at least one sputtering chamber. Two sputtering cathodes are placed at different locations along the path. An inline heater including at least one quartz lamp is placed between the two sputtering cathodes along the path. The first sputtering cathode deposits a layer of material onto the substrate. Subsequently, the substrate and layer are heated by the inline heater before a new layer is added by the second sputtering cathode.

In still another embodiment, the invention provides a method of making a sputtering apparatus that includes an inline interlayer heater. The method includes providing a manufacturing path through at least one sputtering chamber. Three sputtering cathodes are placed along the manufacturing path. The middle sputtering cathode is then replaced with the inline interlayer heater.

The invention provides an apparatus and method for heating a substrate for a recording media. The heating is applied inline and between the deposition of layers on the substrate surface. The present invention utilizes a pass-by sputtering chamber design containing a sputtering cathode and an inline heater including at least one quartz lamp.

According to the domain theory, a magnetic material is composed of a number of submicroscopic regions called domains. Each domain contains parallel atomic magnetic moments and is thus always magnetized to saturation, but the directions of magnetization of different domains are not necessarily parallel. In the absence of an applied magnetic field, adjacent domains may be oriented randomly in any number of several directions, called the directions of easy magnetization, which depend on the geometry of the crystal. The resultant effect of all these various directions of magnetization may be zero, as is the case with an unmagnetized specimen. When a magnetic filed is applied, the domains most nearly parallel to the direction of the applied field grow in size at the expense of the others. This is called boundary displacement of the domains or domain growth. A further increase in magnetic field causes more domains to rotate and align parallel to the applied field. When the material reaches the point of saturation magnetization, no further domain growth would take place on increasing the strength of the magnetic field.

A magnetic material is said to possess a uniaxial anisotropy when it includes only one magnetic easy axis. On the other extreme, a magnetic material is said to be isotropic when no domain orientation is favored.

The ease of magnetization or demagnetization of a magnetic material depends on the crystal structure, grain orientation, the state of strain, and the direction and strength of the magnetic field. The magnetization is most easily obtained along the easy axis of magnetization but most difficult along the hard axis of magnetization.

“Anisotropy energy” is the difference in energy of magnetization for these two extreme directions, namely, the easy axis of magnetization and the hard axis of magnetization. For example, a single crystal of iron, which is made up of a cubic array of iron atoms, tends to magnetize in the directions of the cube edges along which lie the easy axes of magnetization. A single crystal of iron requires about 1.4×10⁵ ergs/cm³ (at room temperature) to move magnetization into the hard axis of magnetization, which is along a cubic body diagonal.

The anisotropy energy U_{A} could be expressed in an ascending power series of the direction cosines between the magnetization and the crystal axes. For cubic crystals, the lowest-order terms take the form of Equation (1),

U_{A}=K₁(α₁²α₂²+α₂²α₃²+α₃²α₁²)+K₂(α₁²α₂²α₃²) (1)

where α₁, α₂ and α₃ are direction cosines with respect to the cube, and K₁ and K₂ are temperature-dependent parameters characteristic of the material, called anisotropy constants.

Anisotropy constants can be determined from (1) analysis of magnetization curves, (2) the torque on single crystals in a large applied field, and (3) single crystal magnetic resonance.

The total energy of a magnetic substance depends upon the state of strain in the magnetic material and the direction of magnetization including three contributions. Two consist of the crystalline anisotropy energy of the unstrained lattice and a correction that takes into account the dependence of the anisotropy energy on the state of strain. A third contribution is that of the elastic energy, which is independent of magnetization direction and is a minimum in the unstrained state. The state of strain of the crystal will be that which minimizes the sum of the energy contributions. The result is that, when magnetized, the lattice is distorted from the unstrained state, unless there is no magnetostriction.

“Magnetostriction” refers to the changes in dimension of a magnetic material when it is placed in magnetic field. It is caused by the rotation of domains of a magnetic material under the action of magnetic field. The rotation of domains gives rise to internal strains in the material, causing its contraction or expansion.

The requirements for high areal density impose increasingly greater requirements on magnetic recording media in terms of coercivity (Hc); magnetic remanance (Mr); coercivity squareness (S*); medium noise, eg., signal-to-medium noise ratio (SMNR); and narrow track recording performance. It is extremely difficult to produce a magnetic recording medium satisfying such demanding requirements, particularly a high-density magnetic rigid disk medium for longitudinal or perpendicular recording. The magnetic anisotropy of longitudinal and perpendicular recording media makes the easily magnetized direction of the media located in the film plane and perpendicular to the film plane, respectively. The remnant magnetic moment of the magnetic media after magnetic recording or writing of longitudinal and perpendicular media is located in the film plane and perpendicular to the film plane, respectively.

Almost all the manufacturing of a disk media takes place in clean rooms where the amount of dust in the atmosphere is kept very low, and is strictly controlled and monitored. After one or more cleaning processes, the substrate has an ultra-clean surface and is ready for the deposition of layers of magnetic media on the substrate. The apparatus for depositing all the layers needed for such media could be a static sputter system or a pass-by system, where all the layers except the lubricant are commonly deposited sequentially inside a suitable vacuum environment.

A substrate material preferably employed in producing magnetic recording rigid disks comprises an aluminum-magnesium (Al—Mg) alloy. Such Al—Mg alloys are preferably electrolessly plated with a layer of NiP at a thickness of about 5-15 microns to increase the hardness of the substrates, thereby providing a suitable surface for polishing to provide the requisite surface roughness or texture.

Other substrate materials have been employed, such as glass, e.g., an amorphous glass, glass-ceramic material which comprises a mixture of amorphous and crystalline materials, and ceramic materials. Glass-ceramic materials do not normally exhibit a crystalline surface. Glasses and glass-ceramics generally exhibit high resistance to shocks.

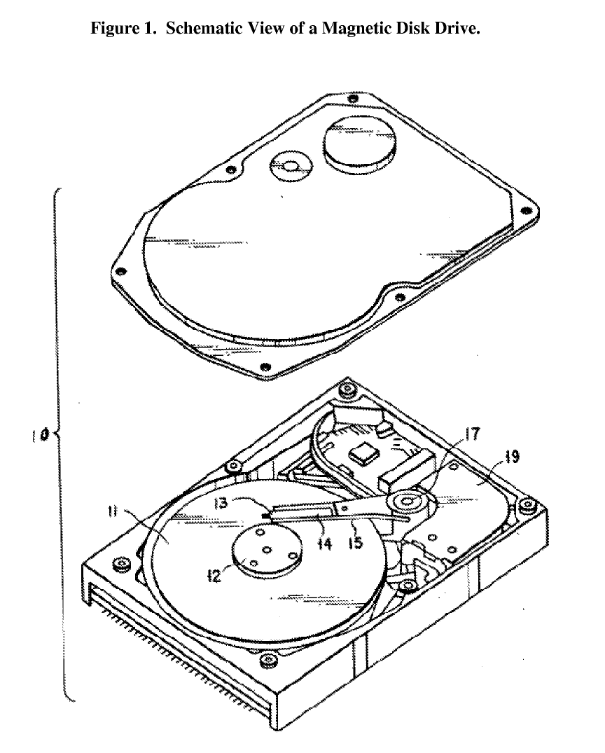

FIG. 1 shows the schematic arrangement of a magnetic disk drive 10 using a rotary actuator. A disk or medium 11 is mounted on a spindle 12 and rotated at a predetermined speed. The rotary actuator comprises an arm 15 to which is coupled a suspension 14. A magnetic head 13 is mounted at the distal end of the suspension 14. The magnetic head 13 is brought into near-contact with the recording/reproduction surface of the disk 11. The rotary actuator could have several suspensions and multiple magnetic heads to allow for simultaneous recording and reproduction on and from both surfaces of each medium.

An electromagnetic converting portion (not shown) for recording/reproducing information is mounted on the magnetic head 13. The arm 15 has a bobbin portion for holding a driving coil (not shown). A voice coil motor 19 as a kind of linear motor is provided to the other end of the arm 15. The voice motor 19 has the driving coil wound on the bobbin portion of the arm 15 and a magnetic circuit (not shown). The magnetic circuit comprises a permanent magnet and a counter yoke. The magnetic circuit opposes the driving coil to sandwich it. The arm 15 is swingably supported by ball bearings (not shown) provided at the upper and lower portions of a pivot portion 17. The ball bearings provided around the pivot portion 17 are held by a carriage portion (not shown).

A magnetic head support mechanism is controlled by a positioning servo driving system. The positioning servo driving system comprises a feedback control circuit having a head position detection sensor (not shown), a power supply (not shown), and a controller (not shown). When a signal is supplied from the controller to the respective power supplies based on the detection result of the position of the magnetic head 13, the driving coil of the voice coil motor 19 and the piezoelectric element (not shown) of the head portion are driven.

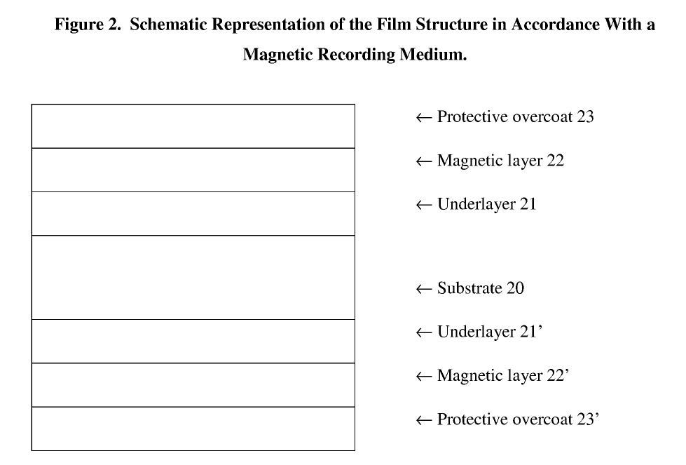

A cross sectional view of a longitudinal recording disk medium is depicted in FIG. 2. A longitudinal recording medium preferably comprises a non-magnetic substrate 20 having sequentially deposited on each side thereof an underlayer 21, 21′, such as chromium (Cr) or Cr-alloy, a magnetic layer 22, 22′, preferably comprising a cobalt (Co)-alloy, and a protective overcoat 23, 23′, preferably containing carbon. practices also comprise bonding a lubricant topcoat (not shown) to the protective overcoat. Underlayer 21, 21′, magnetic layer 22, 22′, and protective overcoat 23, 23′, are preferably deposited by sputtering techniques. The Co-alloy magnetic layer deposited by techniques normally comprises polycrystallites epitaxially grown on the polycrystal Cr or Cr-alloy underlayer.

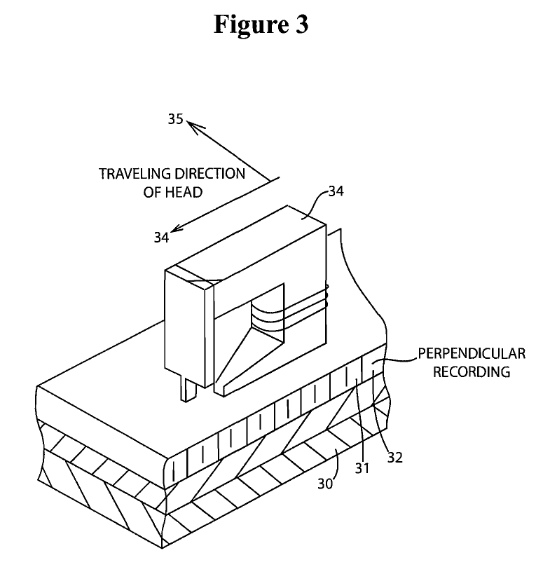

A perpendicular recording disk medium, shown in FIG. 3, is similar to the longitudinal recording medium depicted in FIG. 2, but with the following differences. First, a perpendicular recording disk medium includes a soft magnetic underlayer 31A of an alloy such as Permalloy, deposited between the substrate 30 and underlayer 31. Second, different underlayer materials (commonly an Ru-alloy) replace the a Cr-alloy underlayer, to promote perpendicular anisotropy. Third, as shown in FIG. 3, magnetic layer 32 of the perpendicular recording disk medium comprises domains oriented in a direction perpendicular to the plane of the substrate 30. Also, shown in FIG. 3 are the following: (a) read-write head 33 located on the recording medium, (b) traveling direction 34 of head 33 and (c) transverse direction 35 with respect to the traveling direction 34.

The underlayer and magnetic layer are preferably sequentially sputter deposited on the substrate in an inert gas atmosphere, such as an atmosphere of pure argon. A carbon overcoat is preferably deposited in argon with nitrogen, hydrogen or ethylene. lubricant topcoats are preferably about 10-15 Å thick.

A soft underlayer should preferably be made of soft magnetic materials and the recording layer should preferably include hard magnetic materials. The terms “recording layer” and “magnetic layer” are equivalent and denote the same layer. A soft underlayer is relatively thick compared to other layers. Any layers between the soft underlayer and the recording layer are called interlayer or intermediate layer. An interlayer can be made of more than one layer of non-magnetic materials. The purpose of the interlayer is to prevent an interaction between the soft magnetic underlayer and recording layer. An interlayer could also promote the desired properties of the recording layer. (longitudinal) media do not have a soft magnetic underlayer. Therefore, the layers named as “underlayer,” “seed layer,” “sub-seed layer,” or “buffer layer” of longitudinal media are somewhat equivalent to the intermediate layer(s) of perpendicular media.

It is recognized that the magnetic properties, such as Hc, Mr, S* and SMNR, which are critical to the performance of a magnetic alloy film, depend primarily upon the microstructure of the magnetic layer which, in turn, is influenced by one or more underlying layers on which it is deposited. It is also recognized that an underlayer made of soft magnetic films is useful in perpendicular recording media because it provides a return path for magnetic flux from the read-write head and amplifies a perpendicular component of the write field in the recording layer.

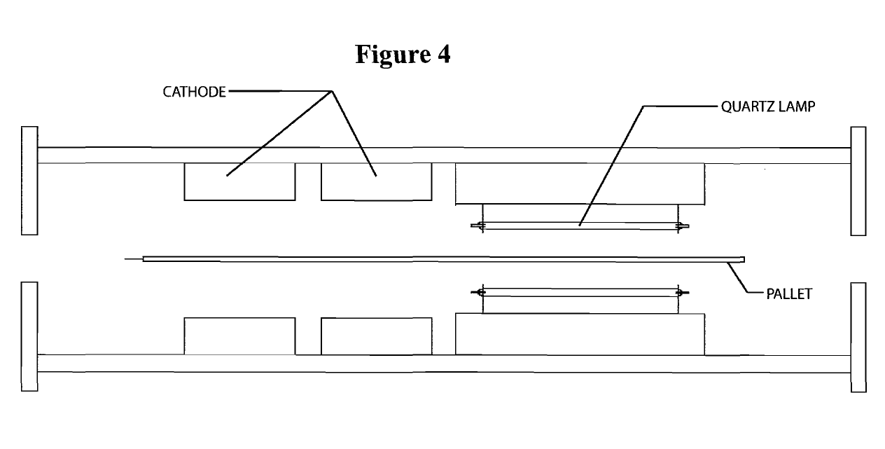

A sputtering chamber in accordance with the invention is shown schematically in FIG. 4. The sputtering chamber has a path along which substrates travel as layers of material are sputtered on either or both of its surfaces. As shown, the substrates are attached to a pallet which is moved through the chamber. Throughout this description the apparatus and method will be described with respect to a single side of the apparatus being layered. However, as shown in FIG. 4, and is typical in the manufacture of recording media, it is certainly feasible for the sputtering cathodes and heaters to be acting on two sides of the substrate.

In accordance with the invention, magnetic recording media may be produced by sputtering a large number of layers of material, both magnetic and non-magnetic, on the surface of a substrate. The overall length of a typical system performing this manufacturing process is quite long. Accordingly, the manufacturing path along which the substrates travel may pass through more than one vacuum sputtering chamber passing a great number of sputtering cathodes. In order to provide a vacuum in the sputtering chambers, a high power pump is provided in one or each chamber. For example, the pump may be a turbo molecular pump, a cryogenic pump or a diffusion pump. Each sputtering cathode includes a sputtering target from which material is sputtered onto the substrate.

In between two sputtering cathodes of the sputtering system along the manufacturing path an inline heater may apply heat to the surface of the substrate. The application of heat to the surface may help anneal the previous layer deposited thereon. Alternatively, or in addition, the heat may help the mobility of atoms that are sputtered onto the surface by a sputtering cathode placed after the heater.

The heater includes at least one quartz lamp which is capable of reaching the desired temperatures for heating the surface of the substrate. In a preferred embodiment, the heater includes a plurality of quartz lamps each of which act together to heat the substrates which are being manufactured. The quartz lamps may be formed as a quartz envelope with a filament therein. The filament is not limited and may be formed of any desirable material, such as tungsten. To improve the performance of the lamp, it may be filled with a gas to protect the filament.

The inline heater and any quartz lamps included therein may be manipulated to provide different heating zones within the heater. As a result, different amounts of heat may be applied to the pallet and substrates as desired. For example, the top of the heater may be operated at a significantly higher temperature than the lower portion of the heater. If inline heaters are included on both sides of the manufacturing path, the zones of the heater can be configured such that the heat applied on either side of the substrate is the same. Alternatively, the heating zones may be configured in different ways.

A particular advantage of the inline heaters of the present invention is that they may be used with manufacturing systems that have already been manufactured and assembled. Rather than building an entirely new system when a process which requires interlayer heating, the inline heaters of the present invention may be used by replacing one or more sputtering cathodes with the heater. In a preferred embodiment, the inline heater may occupy the area of two sputtering cathodes within the sputtering chamber. A further advantage of the system is that the heater, or portions thereof, may use the cathode body of the sputtering chamber as a power source. In other words, at least one quartz lamp of the inline heater may be connected to the cathode body that was being utilized by the replaced sputtering cathode. The other contact of the quartz lamp may be grounded to the sputtering chamber or outside thereof. This is particularly advantageous because it allows the inline heater to take advantage of the high power and expensive conductor that is already available.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein.

As shown, the present invention advantageously provides, as by an apparatus and accompanying processing techniques which can be reliably practiced at low cost, improved methodologies and instrumentalities for forming disks to yield substrates with reliable inner and outer dimensions facilitating their use as substrates for high areal density thin film magnetic and/or MO recording media.

In the previous description, numerous specific details are set forth, such as specific materials, structures, reactants, processes, etc., in order to provide a better understanding of the present invention. However, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in various other combinations and environments and is susceptible of changes and/or modifications within the scope of the inventive concept as expressed herein. The implementations described above and other implementations are within the scope of the following claims.

We claim:

1. A pass-by sputtering chamber, comprising:
a path along which substrates progress as layers are sputtered thereon;
a sputtering cathode disposed at a first location along the path; and
an inline heater disposed at a second location along the path,
wherein the inline heater comprises at least one quartz lamp.

2. The pass-by sputter chamber according to claim 1, wherein the inline heater comprises a plurality of quartz lamps.

3. The pass-by sputter chamber according to claim 2, wherein at least two of the plurality of quartz lamps operate at different temperatures.

4. The pass-by sputter chamber according to claim 1, wherein the sputtering cathode is a first sputtering cathode disposed on a first side of the path, and
wherein the pass-by sputter chamber further comprises a second sputtering cathode disposed on a second side of the path.

5. The pass-by sputter chamber according to claim 1, wherein the inline heater is a first inline heater disposed on a first side of the path, and
wherein the pass-by sputter chamber further comprises a second inline heater disposed on a second side of the path.

6. The pass by sputter chamber according to claim 5, wherein the second inline heater is opposite the first inline heater.

7. The pass-by sputter chamber according to claim 1, wherein the pass-by sputter chamber is a vacuum chamber.

8. The pass-by sputter chamber according to claim 1, wherein the quartz lamp comprises a quartz envelope and a filament.

9. The pass-by sputter chamber according to claim 1, wherein the inline heater occupies a first length along the path,
wherein the sputtering cathode occupies a second length along the path, and
wherein the first length is approximately twice the second length.

10. The pass-by sputter chamber according to claim 1, wherein the inline heater comprises a plurality of heating zones, and
wherein at least two heating zones operate at different temperatures.

11. The pass-by sputter chamber according to claim 5, wherein the first and second inline heaters each comprise a plurality of zones, and
wherein at least two heating zones of each or the first and second inline heaters operate at different temperatures.

12. The pass-by sputter chamber according to claim 11, wherein the heating zones of the first inline heater are identical to the heating zones of the second inline heater, and
wherein each zone of the first inline heater operates at the same temperature as a corresponding zone of the second inline heater.

13. A method of forming layers of a substrate comprising:
providing a manufacturing path through at least one sputtering chamber;
providing a first sputtering cathode at a first location along the manufacturing path;
providing an inline heater at a second location along the manufacturing path, the inline heater comprising at least one quartz lamp;
providing a second sputtering cathode at a third location along the manufacturing path;
sputtering a first layer of material onto the substrate using the first sputtering cathode;
heating the substrate and first layer of material using the inline heater; and
sputtering a second layer of material onto the substrate using the second sputtering cathode.

14. The method of claim 13 wherein the inline heater includes a plurality of quartz lamps.

15. The method of claim 14 further comprising:
setting a first of the plurality of quartz lamps to a first temperature; and
setting a second of the plurality of quartz lamps to a second temperature,
wherein the first and second temperatures are different.

16. A method of making a sputtering apparatus comprising:
providing a manufacturing path through at least one sputtering chamber;
providing at least first, second and third cathode bodies along the manufacturing path;
forming a first sputtering cathode by attaching at least a sputter target to the first cathode body;
forming a second sputtering cathode by attaching at least a sputter target to the second cathode body;
forming a third sputtering cathode by attaching at least a sputter target to the third cathode body, wherein the second sputtering cathode is between the first sputtering cathode and the third sputtering cathode along the manufacturing path;
removing the second sputtering cathode by at least detaching the sputtering target from the second sputtering cathode; and
connecting at least one quartz lamp to the second cathode body.

17. The method of claim 16 wherein the at least one quartz lamp is part of an inline heater.

18. The method of claim 17 further comprising providing a fourth sputtering cathode between the first and third sputtering cathodes along the manufacturing path,
removing the fourth sputtering cathode prior to connecting the at least one quartz lamp to the second cathode body,
wherein the inline heater partially lies in the area previously occupied by the fourth sputtering cathode.
